(19) United States
(12) Patent Application Publication
(10) Pub. No.: US 2007/0242530 A1
(43) Pub. Date: Oct. 18, 2007

(54) MEMORY CONTROLLER FOR SUPPORTING DOUBLE DATA RATE MEMORY AND RELATED METHOD

(76) Inventors: Hsiang-I Huang, Hsinchu City (TW); Ta-Lun Huang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/279,750

(22) Filed: Apr. 13, 2006

(51) Int. Cl. G11C 7/10

(52) U.S. Cl. 365/189.02

(57) ABSTRACT

A memory controller includes a first data converter for converting incoming data into a first data in which a bit width of the incoming data and a bit width of the first data corresponds to a first ratio; a second data converter for converting the incoming data into a second data where the bit width of the incoming data and a bit width of the second data corresponds to a second ratio; and a first selector, coupled to the first and second data converters, for outputting either the first data or the second data to a memory device according to a memory mode setting.

### BACKGROUND

The present invention relates to memory devices, and more particularly, to memory controllers for supporting double data rate (DDR) memories and related methods.

In normal memories, read and write operations take place only on the rising or falling edge of a clock signal, but data in DDR (double data rate) memories are read and written both on rising edges and falling edges of the clock signal. Accordingly, DDR memories can provide doubled data throughput compared to the single data rate memories.

Please refer to FIG. 1, which depicts a simplified schematic diagram of a conventional memory system 100. As shown, the memory system 100 comprises a memory controller 110, a DDR memory 120, a memory bus 130, and an on-chip bus 140. The memory bus 130 is arranged for communicating between the memory controller 110 and the DDR memory 120. The on-chip bus 140 is arranged for communicating between the memory controller 110 and other components needed to access the DDR memory 120, such as a CPU, a north bridge circuit, etc. In the related art, since the DDR memory 120 can transfer two memory words in one cycle, the on-chip bus 140 is typically designed to have a bus width double that of the memory bus 130. In other words, if the bus width of the memory bus 130 is N bits, then the on-chip bus 140 is designed to have a bus width of 2N bits.

In such architecture, the memory controller 110 needs to operate at the same operating frequency as the DDR memory 120. For example, if the DDR memory 120 is a DDR-I 400 memory, the memory controller 110 and the DDR-I 400 memory both need to operate at 200 MHz. Similarly, if the DDR memory 120 is a DDR-II 800 memory, then the memory controller 110 needs to operate at 400 MHz. The cycle time of 400 MHz is only 2.5 ns, which is difficult to achieve by adopting modern CMOS manufacturing processes. Although this can be achieved by utilizing great engineering effort, this is obviously not a good solution when the manufacturing cost, chip size, yield rate, and required human resources are taken into account. In view of the foregoing, the architecture of the conventional memory system 100 is not feasible for supporting both the DDR-I and DDR-II memories.

### SUMMARY OF THE INVENTION

An exemplary embodiment of a memory controller is disclosed comprising: a first data converter for converting incoming data into a first data, a bit width of the incoming data and a bit width of the first data corresponding to a first ratio; a second data converter for converting incoming data into a second data, the bit width of the incoming data and a bit width of the second data corresponding to a second ratio; and a first selector, coupled to the first and second data converters and the register, for outputting either the first data or the second data to a memory device according to a memory mode setting.

An exemplary embodiment of a memory controller is disclosed comprising: a first data converter for converting data received from a memory device into a first data, a bit width of the data received from the memory device and a bit width of the first data corresponding to a first ratio; a second data converter for converting data received from the memory device into a second data, a bit width of the data received from the memory device and a bit width of the second data corresponding to a second ratio; and a selector, coupled to the first and second data converters and the register, for outputting either the first data or the second data according to a memory mode setting.

An exemplary embodiment of a method for writing a target data into a memory device is disclosed comprising: converting the target data into a first data in which a bit width of the target data and a bit width of the first data corresponds to a first ratio; converting the target data into a second data in which the bit width of the target data and a bit width of the second data corresponds to a second ratio; and selectively outputting the first data or the second data to the memory device according to the type of the memory device.

An exemplary embodiment of a method for reading a memory device is disclosed comprising: converting data received from the memory device into a first data where a bit width of the data received from the memory device and a bit width of the first data corresponds to a first ratio; converting data received from the memory device into a second data where a bit width of the data received from the memory device and a bit width of the second data corresponding to a second ratio; and selectively outputting either the first data or the second data according to the type of the memory device.

### BRIEF DESCRIPTION OF THE DRAWINGS

FIG. 1 is a simplified schematic diagram of a conventional memory system.

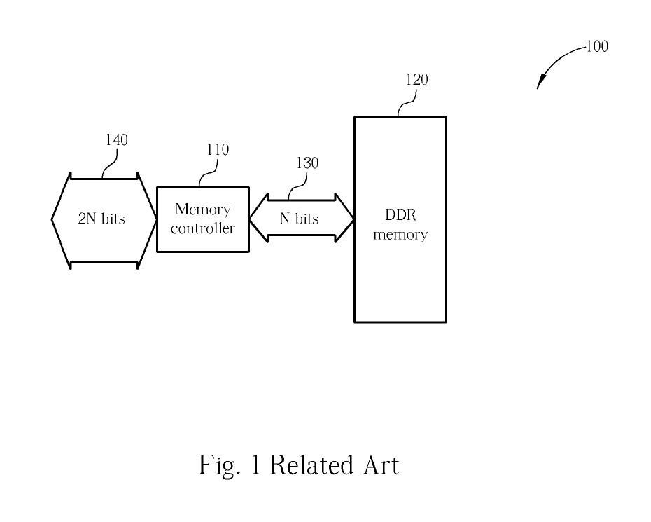

FIG. 2 is a simplified schematic diagram of a memory system according to a first embodiment.

FIG. 3 is a simplified block diagram of a memory controller of FIG. 2 according to an exemplary embodiment.

FIG. 4 is a simplified schematic diagram of a memory system according to a second embodiment.

FIG. 5 is a simplified block diagram of a memory controller of FIG. 4 according to an exemplary embodiment.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

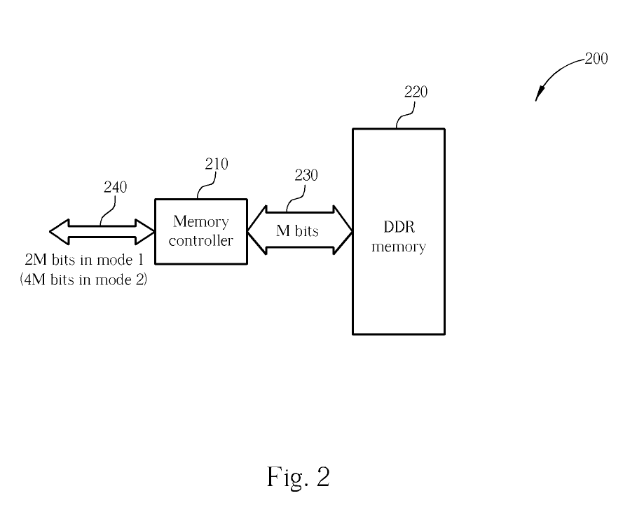

Please refer to FIG. 2, which shows a simplified schematic diagram of a memory system 200 according to a first embodiment. The memory system 200 comprises a memory controller 210, a DDR memory 220 coupled to the memory controller 210 through a memory bus 230, and an on-chip bus 240 coupled to the memory controller 210. The on-chip bus 240 is arranged for communicating between the memory controller 210 and other components needed to access the DDR memory 220 such as a CPU, a north bridge circuit, etc. In this embodiment, the memory controller 210 has two operating modes: mode 1 and mode 2, depending on the type of DDR memory 220. For the purpose of explanatory convenience in the following description, it is herein assumed that the memory controller 210 operates in mode 1 when the DDR memory 220 is a DDR-I memory, and operates in mode 2 when the DDR memory 220 is a DDR-II memory. Accordingly, mode 1 can also be referred to as DDR-I mode and mode 2 can also be referred to as DDR-II mode. In different operating modes, the on-chip bus 240 of this embodiment has different active bus widths. In one aspect, the active bus width of the on-chip bus 240 is determined by the type of DDR memory 220.

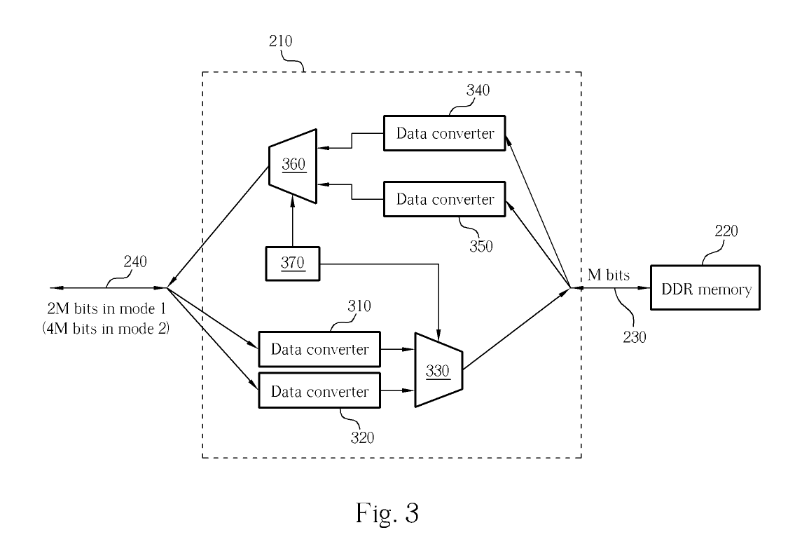

In the embodiment shown in FIG. 2, the physical bus width of the memory bus 230 is M bits and the physical bus width of the on-chip bus 240 is 4M bits, but the active bus width of the on-chip bus 240 is 2M bits in mode 1 and 4M bits in mode 2. In other words, the memory controller 210 utilizes only a half of the on-chip bus 240 in mode 1 (i.e. the DDR-I mode), and utilizes the whole on-chip bus 240 in mode 2 (i.e. the DDR-II mode). In such a design, the memory controller 210 can operate at the same operating frequency as the DDR memory 220 when the DDR memory 220 is a DDR-I memory, and only needs to operate at half the operating frequency of the DDR memory 220 when the DDR memory 220 is a DDR-II memory. If the highest operating frequencies of the DDR-I memory and DDR-II memory are 200 MHz and 400 MHz respectively, the memory controller 210 only needs to operate at 200 MHz at most, instead of 400 MHz. Hereinafter, operations and implementations of the memory controller 210 will be explained with reference to FIG. 3.

FIG. 3 is a simplified block diagram of the memory controller 210 according to an exemplary embodiment. In this embodiment, the memory controller 210 comprises a first data converter 310, a second data converter 320, a first selector 330, a third data converter 340, a fourth data converter 350, a second selector 360, and a register 370. The register 370 is arranged for storing a memory mode setting corresponding to the type of DDR memory 220. In one aspect, the operating mode of the memory controller 210 is determined by the memory mode setting stored in the register 370. Accordingly, the operating mode of the memory controller 210 can be adjusted by programming the register 370.

As shown in FIG. 3, the first and second data converters 310 and 320 are coupled to and disposed between the on-chip bus 240 and the first selector 330. The third and fourth data converters 340 and 350 are coupled to and disposed between the memory bus 230 and the second selector 360. In this embodiment, the lower half of the memory controller 210 is utilized for processing data to be written into the DDR memory 220, and the upper half of the memory controller 210 is utilized for processing data retrieved from the DDR memory 220.

In data writing operations, the memory controller 210 receives a target data to be written into the DDR memory 220 through the on-chip bus 240. The first data converter 310 converts the target data into a first data, and the second data converter 320 converts the target data into a second data, wherein a bit width of the target data and a bit width of the first data correspond to a first ratio while the bit width of the target data and a bit width of the second data correspond to a second ratio. In this embodiment, the first ratio is two to one and the second ratio is four to one. The first selector 330 is arranged for outputting either the first data or the second data to the DDR memory 220 according to the memory mode setting stored in the register 370. Specifically, if the DDR memory 220 is a DDR-I memory, the first selector 330 outputs the first data generated from the first data converter 310 to the memory bus 230 to write the first data into the DDR memory 220. On the other hand, if the DDR memory 220 is a DDR-II memory, the first selector 330 outputs the second data generated from the second data converter 320 to the memory bus 230 for writing the second data into the DDR memory 220. In practice, the first data converter 310 and the second data converter 320 may both be implemented with a de-multiplexer and the first selector 330 may be realized by a multiplexer.

In data reading operations, data to be read is retrieved from the DDR memory 220 and then transmitted to the memory controller 210 through the memory bus 230. For the purpose of explanatory convenience in the following description, the data retrieved from the DDR memory 220 is hereinafter referred to as a readout data. The third data converter 340 converts the readout data received from the DDR memory 220 into a third data, and the fourth data converter 350 converts the readout data into a fourth data, wherein a bit width of the readout data and a bit width of the third data correspond to a third ratio while the bit width of the readout data and a bit width of the fourth data corresponding to a fourth ratio. In this embodiment, the third ratio is one to two and the fourth ratio is one to four. The second selector 360 outputs either the third data or the fourth data to the on-chip bus 240 according to the memory mode setting stored in the register 370. If the DDR memory 220 is a DDR-I memory, the second selector 360 outputs the third data generated from the third data converter 340 to the on-chip bus 240 for transmitting the readout data to the component requesting the readout data. On the other hand, if the DDR memory 220 is a DDR-II memory, the second selector 360 outputs the fourth data generated from the fourth data converter 350 to the on-chip bus 240. In practice, the third data converter 340, the fourth data converter 350, and the second selector 360 may each be realized by a multiplexer.

According to the foregoing descriptions, it can be appreciated that the memory controller 210 and the on-chip bus 240 can operate at the same operating frequency as the DDR memory 220 when the DDR memory 220 is a DDR-I memory. For example, the on-chip bus 240 can operate at 200 MHz when the DDR memory 220 is a DDR-I 400 memory. If the DDR memory 220 is a DDR-II memory, the memory controller 210 and the on-chip bus 240 only need to operate at half the operating frequency of the DDR memory 220 due to the active bus width of the on-chip bus 240 being four times the active bus width of the memory bus 230. By way of example, when the DDR memory 220 is a DDR-II 800 memory, the on-chip bus 240 only needs to operate at 200 MHz instead of 400 MHz. As a result, the memory controller 210 can be produced by adopting modern CMOS manufacturing processes without too much extra engineering effort.

In the foregoing memory system 200, the bus width of the memory bus 230 is fixed and the bus width of the on-chip 240 is scalable or changeable. This is merely an embodiment rather than a restriction of the practical implementations.

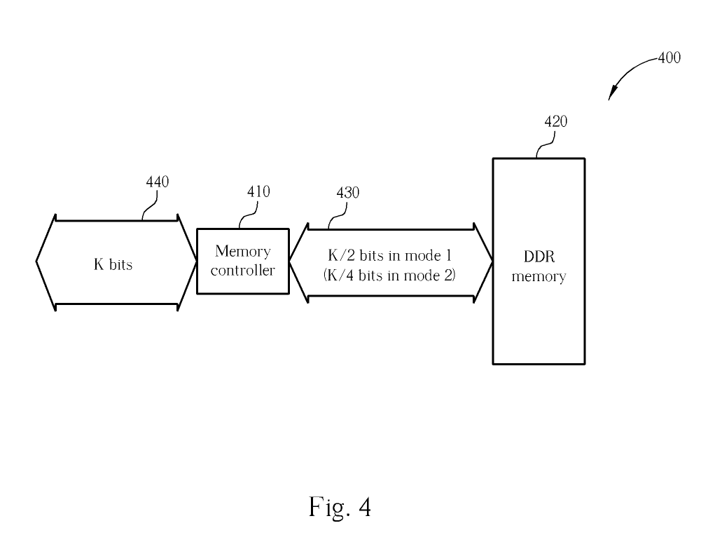

For example, FIG. 4 shows a simplified schematic diagram of a memory system 400 according to a second embodiment. The memory system 400 comprises a memory controller 410, a DDR memory 420 coupled to the memory controller 410 through a memory bus 430, and an on-chip bus 440 for communicating between the memory controller 410 and other components. Similar to the memory controller 210, the memory controller 410 also has two operating modes: mode 1 and mode 2, depending on the type of DDR memory 420. In this embodiment, mode 1 and mode 2 are also assumed to be DDR-I mode and DDR-II mode respectively. Note that, the memory bus 430 of this embodiment has different active bus widths in different operating modes but the active bus width of the on-chip bus 440 is fixed whether the DDR memory 420 is a DDR-I memory or a DDR-II memory. In one aspect, the active bus width of the memory bus 430 is determined by the type of DDR memory 420.

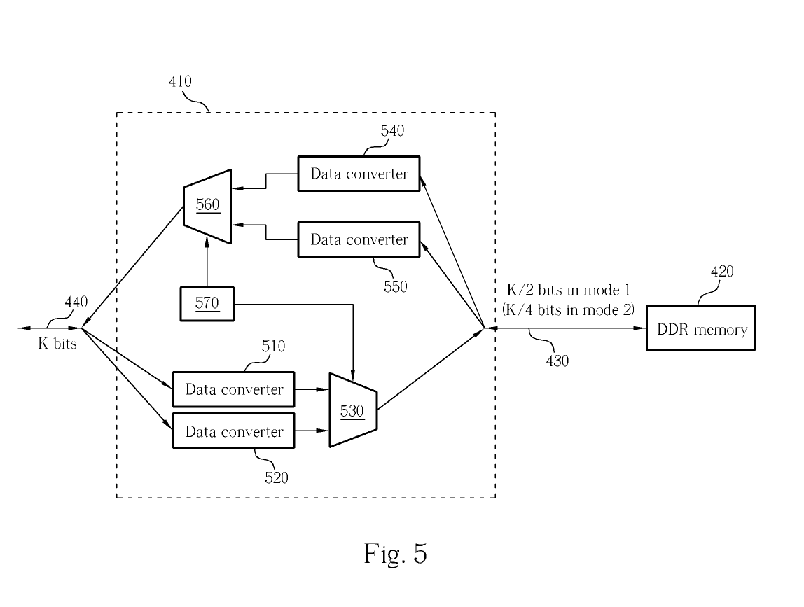

For example, the physical bus width of the on-chip bus 440 of this embodiment is K bits and the physical bus width of the memory bus 430 is K/2 bits, but the active bus width of the memory bus 430 is K/2 bits in mode 1 and is K/4 bits in mode 2. In other words, the memory controller 410 of this embodiment can support a K/2 bits DDR-I memory bus and a K/4 bits DDR-II memory bus. In operating mode 1 (i.e. DDR-I mode), since the active bus width of the on-chip bus 440 is two times the active bus width of the memory bus 430, the memory controller 410 operates at the same operating frequency as the DDR memory 420. In mode 2 (i.e. DDR-II mode), since the active bus width of the on-chip bus 440 is four times the active bus width of the memory bus 430, the memory controller 410 only needs to operate at half the operating frequency of the DDR memory 420. Similar to the memory controller 210 described previously, the memory controller 410 only needs to operate at 200 MHz at most, instead of 400 MHz, to support both the DDR-I memory and DDR-II memory. Operations and implementations of the memory controller 410 will be described below with reference to FIG. 5.

FIG. 5 is a simplified block diagram of the memory controller 410 according to an exemplary embodiment. The memory controller 410 comprises a first data converter 510, a second data converter 520, a first selector 530, a third data converter 540, a fourth data converter 550, a second selector 560, and a register 570. The register 570 is utilized for storing a memory mode setting corresponding to the type of DDR memory 420, and the operating mode of the memory controller 410 is determined by the memory mode setting.

In data writing operations, the first data converter 510, the second data converter 520, and the first selector 530 operate in substantially the same way as (respectively) the first data converter 310, the second data converter 320, and the first selector 330 in the memory controller 210. In data reading operations, the third data converter 540, the fourth data converter 550, and the second selector 560 operate in substantially the same way as (respectively) the third data converter 340, the fourth data converter 350, and the second selector 360 in the memory controller 210. In practice, the first data converter 510 and the second data converter 520 may both be implemented with de-multiplexers. The first selector 530, the second selector 560, the third data converter 540, and the fourth data converter 550 may each be a multiplexer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory controller comprising:
a first data converter for converting incoming data into a first data, a bit width of the incoming data and a bit width of the first data corresponding to a first ratio;
a second data converter for converting the incoming data into a second data, the bit width of the incoming data and a bit width of the second data corresponding to a second ratio; and
a first selector, coupled to the first and second data converters, for outputting either the first data or the second data to a memory device according to a memory mode setting.

2. The memory controller of claim 1, wherein the first or second data converter is a de-multiplexer.

3. The memory controller of claim 1, wherein the first selector is a multiplexer.

4. The memory controller of claim 1, further comprising:
a third data converter for converting data received from the memory device into a third data, a bit width of the data received from the memory device and a bit width of the third data corresponding to a third ratio;
a fourth data converter for converting the data received from the memory device into a fourth data, the bit width of the data received from the memory device and a bit width of the fourth data corresponding to a fourth ratio; and
a second selector, coupled to the third and fourth data converters and the register, for outputting either the third data or the fourth data according to the memory mode setting.

5. The memory controller of claim 4, wherein the third or fourth data converter is a multiplexer.

6. The memory controller of claim 4, wherein the second selector is a multiplexer.

7. The memory controller of claim 4, wherein the third ratio is one to two and the fourth ratio is one to four.

8. The memory controller of claim 1, wherein the memory mode setting corresponds to the type of the memory device.

9. The memory controller of claim 8, wherein the memory device is a DDR-I memory or a DDR-II memory.

10. The memory controller of claim 1, wherein the first ratio is two to one and the second ratio is four to one.

11. The memory controller of claim 1, further comprising a register coupled to the first selector for storing the memory mode setting.

12. A memory controller comprising:
a first data converter for converting data received from a memory device into a first data, a bit width of the data received from the memory device and a bit width of the first data corresponding to a first ratio;
a second data converter for converting data received from the memory device into a second data, a bit width of the data received from the memory device and a bit width of the second data corresponding to a second ratio; and
a selector, coupled to the first and second data converters and the register, for outputting either the first data or the second data according to a memory mode setting.

13. The memory controller of claim 12, wherein the first or second data converter is a de-multiplexer.

14. The memory controller of claim 12, wherein the selector is a multiplexer.

15. The memory controller of claim 12, wherein the memory mode setting corresponds to the type of the memory device.

16. The memory controller of claim 15, wherein the memory device is a DDR-I memory or a DDR-II memory.

17. The memory controller of claim 12, wherein the first ratio is one to two and the second ratio is one to four.

18. The memory controller of claim 12, further comprising a register coupled to the first selector for storing the memory mode setting.

19. A method for writing a target data into a memory device, comprising:
converting the target data into a first data in which a bit width of the target data and a bit width of the first data corresponds to a first ratio;
converting the target data into a second data in which the bit width of the target data and a bit width of the second data corresponds to a second ratio; and
selectively outputting the first data or the second data to the memory device according to the type of the memory device.

20. The method of claim 19, wherein the memory device is a DDR-I memory or a DDR-II memory.

21. The method of claim 19, wherein the first ratio is two to one and the second ratio is four to one.

22. A method for reading a memory device, comprising:
converting data received from the memory device into a first data where a bit width of the data received from the memory device and a bit width of the first data corresponds to a first ratio;
converting data received from the memory device into a second data where a bit width of the data received from the memory device and a bit width of the second data corresponds to a second ratio; and
selectively outputting either the first data or the second data according to the type of the memory device.

23. The method of claim 22, wherein the memory device is a DDR-I memory or a DDR-II memory.

24. The method of claim 22, wherein the first ratio is one to two and the second ratio is one to four.
